(19) United States
(12) Patent Application Publication
(10) Pub. No.: US 2006/0045300 A1
(43) Pub. Date: Mar. 2, 2006

(54) Loudspeaker With An Integrated Woofer Frame And Baffle Component

(75) Inventor: Frank Sterns, Miami, FL (US)

Correspondence Address: LOTT & FRIEDLAND, P.A., P.O. BOX 141098, CORAL GABLES, FL, 33114-1098, US

(73) Assignee: NILES AUDIO CORPORATION, Miami, FL (US)

(21) Appl. No.: 10/711,218

(22) Filed: Sep. 2, 2004

(51) Int. Cl. H05K 5/00; H04R 1/02; H04R 1/20

(52) U.S. Cl. 381/345; 381/347; 381/162

(57) ABSTRACT

A loudspeaker assembly with an integrated woofer frame and baffle component wherein the woofer frame is created as an integral part of the baffle by molding the woofer frame and baffle as a unitary component.

### FIELD OF INVENTION

This invention relates generally to a loudspeaker with an integrated woofer frame and baffle component. This invention relates in particular to a loudspeaker assembly where the woofer frame is created as an integral part of the baffle by molding the woofer frame and baffle as a unitary component.

### BACKGROUND OF THE INVENTION

The home audio industry places great emphasis on convenience and sound quality. A company that can provide high-fidelity speakers that are engineered intelligently to suit the varied purposes of the consumer can be very successful in the multi-billion dollar annual sales market in the United States and abroad.

While many varieties of speaker exist, performing various roles, these traditional speakers typically require the use of a metallic woofer frame in order to provide a structure to which the various speaker components will attach. This woofer frame is used in addition to the baffle that provides a face for the speaker and any additional space for the attachment of additional speakers. This method of assembling speakers contains a number of inherent disadvantages.

First, the woofer frame is large enough that many of the speaker components can fit within its bowl-like shape, which must then fit within the baffle. Such a configuration occupies more space than is necessary. Additional disadvantages to the current method of construction are derived from the use of a metallic frame. The use of a metallic frame reduces the quality of the audio output of the speaker because the metal absorbs energy from the speaker motor, which incorporates a magnet. The metal is also more susceptible to weather in the event the speaker is used outdoors. Finally, the traditional configuration requires additional hand labor for assembly, which is costly and inefficient.

Previous attempts have been made to provide speakers with components to direct sound for optimal listening such as are described in U.S. Pat. No. 6,493,455 to Tracy (the '455 patent) U.S. Publication No. 2002/0097888 to Tracy (the '888 publication); U.S. Pat. No. D450,683 to Vosse (the '683 patent); U.S. Pat. No. 5,533,132 to Button (the '132 patent); U.S. Pat. No. 4,928,312 to Hill (the '312 patent); U.S. Pat. No. 4,680,676 to Petratos, et al. (the '676 patent); U.S. Pat. No. D271,967 to Meyer, et al. (the '967 patent) and U.S. Pat. No. 4,330,691 to Gordon (the '691 patent).

The '455 patent describes a loudspeaker assembly including a housing having a central driver mounting plate upon which a driver is mounted. The central driver mounting plate and the driver divide the housing into an upper compartment and a lower compartment, wherein the lower compartment includes at least one slot providing fluid communication between an interior of the lower compartment and an external environment.

The '888 publication describes a subwoofer assembly for use within an aircraft including a fuselage having a passenger platform, wherein the passenger platform includes an aisle and a seating area. The subwoofer assembly is shaped and dimensioned for positioning under the aisle. The subwoofer assembly includes a subwoofer housing having a profile shaped to substantially conform to a position beneath the passenger platform under the aisle. The subwoofer housing includes a sound port through which sound is delivered from the subwoofer assembly to a passenger compartment of the aircraft. The subwoofer assembly further including a sound driver mounted within the subwoofer housing for generating predetermined sounds.

The '683 patent describes a design for an integrated baffle for a loudspeaker. From the patent figures of the '683 patent it would appear that the integrated baffle design contains openings for the tweeter and woofer along with openings in between the tweeter and woofer openings near the outside edges of the baffle.

The '132 patent describes total thermal management accomplished by self-cooling from acoustic air movement in a light-weight loudspeaker system for professional sound applications. A cast aluminum front panel, forming the front baffle portion of a total enclosure, is configured to include on the front panel a horn opening, a woofer opening with a ring mount for a conventional woofer cone, a pair of bass reflex ports, and, extending rearwardly, a woofer frame with a mount for a conventional woofer driver, a horn structure with a threaded mount for a conventional horn driver, and an amplifier mounting shelf, all thermally combined by a pattern of generally vertical integral cooling vanes. The lower portions of the vanes are shaped to form structural legs of the woofer frame, and their upper portions are integrally attached to the horn. A shelf for mounting an amplifier in the speaker enclosure is formed by a transverse cooling vane. All of the heat-producing devices are thermally connected via good heat-conduction paths provided by the vanes attached integrally to densely-vaned cooling grilles forming the tuned reflex ports; thus, as the woofer is energized, air moves in and out of the grilles at high velocity particularly at low frequency resonance, acting like a fan on the grilles and thus enhancing their thermal dissipation with a cooling effect that increases as the woofer plays louder due to the increased velocity of the reciprocal air movement.

The '312 patent describes an acoustic transducer loudspeaker for converting variations of electrical energy into corresponding variations of acoustic energy formed of one piece of foamed polymer material having different densities in different portions thereof. The one piece of foamed polymer material has a periphery portion of one density and a diaphragm portion formed in the center thereof and a resilient diaphragm suspension portion separating the periphery portion from the diaphragm portion and having a flexible polymer insert attached in a recess over the diaphragm suspension portion. A voice coil is fixedly attached to the diaphragm portion and a frame is mounted to the foamed polymer sheet periphery portion and extends over the diaphragm portion to support a permanent magnet thereon for alignment with the voice coil. A laminated cover panel can be laminated to the front of the foamed polymer sheet to provide a speaker and a ceiling tile or wall panel without a visible grill.

The '676 patent describes a portable radio housing having a shield that provides electromagnetic isolation between logic and radio boards operating on close frequencies. The radio board is positioned in a conductive frame having fours sides surrounding a central opening. A tab on the frame is connected to a power module on the radio board to sink heat from the power module. A middle shield having sides with integral spring fingers at calculated intervals is attached to the frame over the rear surface of the radio board. A logic board and rear shield are attached to the frame over the middle shield. A connector protrudes through an opening in the middle shield and interconnects the logic and radio boards. A front shield, also having sides with integral spring fingers, is attached to the frame over the front surface of the radio board. The front shield has an integral speaker baffle and tabs for holding a connector. An outer housing and keypad/display module enclose the frame. Electrostatic discharge protection is provided by connecting exposed metal parts to the frame.

The '967 patent claims a design for a speaker. The design includes openings for a woofer, tweeter and two small circular openings near the bottom portion of the speaker.

The '691 patent describes a loudspeaker formed integrally with a rectangular ceiling tile which is provided with electrical contacts for connecting the loudspeaker in series or parallel combinations with other loudspeaker-tile assemblies and for supplying power to the loudspeaker from a bus, such as the T-bar which supports the ceiling tile in a typical suspended ceiling installation. A plurality of these loudspeaker-tile assemblies can be used as part of either the ceiling or wall of a large room into which sound is to be transmitted. The loudspeakers are completely concealed from view. Different electrical delay lines can be connected to various speakers in the array of speakers to produce desired acoustical effects.

None of the devices mentioned above describe a loudspeaker assembly with an integrated woofer frame and baffle component. Additionally, none of the above mentioned patents teach a loudspeaker assembly where the woofer frame is created as an integral part of the baffle by molding the woofer frame and baffle as a unitary component.

Therefore, there is a need in the art for a loudspeaker assembly that can enable a larger woofer to fit in a smaller baffle and speaker cabinet.

There is a further need in the art for a loudspeaker assembly which can reduce the hand labor of installing the woofer frame.

There is still a further need in the art for a loudspeaker assembly that can improve the speaker's weather resistance.

There is yet a further need in the art for a loudspeaker assembly that improves the performance of the speaker because the non-metallic baffle acting as a woofer frame does not absorb magnetic energy from the motor system.

### SUMMARY OF THE INVENTION

The current invention satisfies the needs in the industry by providing a speaker that incorporates the traditional speaker components with a non-metallic, integrated baffle and woofer frame.

In a preferred embodiment of the invention a loudspeaker assembly is provided, comprising: a baffle, wherein the baffle is constructed of a non-metallic substance; a tweeter assembly attached to the baffle; a woofer frame, wherein said woofer frame is an integral part of said baffle; and a woofer assembly, wherein said woofer assembly is mounted within said woofer frame.

In an alternative embodiment, the invention provided is a loudspeaker assembly for outdoor use, comprising: a baffle, wherein said baffle is constructed of a non-metallic substance; a tweeter assembly attached to said baffle; a woofer frame, wherein said woofer frame is an integral part of said baffle; and, a woofer assembly, wherein said woofer assembly is mounted within said woofer frame.

In yet another alternative embodiment, the invention provided is a loudspeaker assembly for outdoor use, comprising: a baffle, wherein the baffle is constructed of a non-metallic substance; a tweeter assembly attached to the baffle; a woofer frame, wherein said woofer frame is an integral part of said baffle; and, a woofer assembly, wherein said woofer assembly is mounted within said woofer frame, and the woofer assembly comprises of a back plate, a magnet, a top plate, and a low frequency transducer, the low frequency transducer comprising a coil, a spider, a surround and a cone.

In another embodiment, the invention provided is a loudspeaker assembly wherein a woofer frame and a baffle are one unitary component of said loudspeaker.

In the various embodiments, the non-metallic baffle can be reinforced to reduce flex. In several embodiments, the woofer assembly is installed into a loudspeaker by mounting the woofer assembly from the front of the loudspeaker.

Therefore, it is an object of the present invention to provide a loudspeaker assembly that can enable a larger woofer to fit in a smaller woofer frame. The loudspeaker assembly of the present invention also allows the loudspeaker to produce higher bass output from smaller cabinets, due to greater woofer cone area that the integrated woofer frame and baffle construction makes possible.

It is further object of the present invention to provide a loudspeaker assembly which can reduce the hand labor of installing the woofer.

It is an additional object of the present invention to provide a loudspeaker assembly that can improve the speaker's weather resistance.

It is a further object of the present invention to provide a loudspeaker assembly that improves the performance of the speaker because the non-metallic baffle, which includes and is integral with the woofer frame, does not absorb magnetic energy from the motor system. Optionally, the loudspeaker may contain a smaller magnet while producing the same output of a larger magnet, because the woofer frame does not absorb magnetic energy.

It is an additional object of the present invention to provide a loudspeaker with little or no sound deflection caused by the ledge of the woofer frame, baffle and woofer assembly mount. The woofer assembly of the present invention is mounted from the face or front of the speaker, allowing for little or no edge to deflect sound.

These and other objects, features, and advantages of the present invention may be better understood and appreciated from the following detailed description of the embodiments thereof, selected for purposes of illustration and shown in the accompanying drawings.

### BRIEF DESCRIPTION OF THE DRAWINGS

FIG. 1 shows a rear perspective view of the preferred embodiment of the loudspeaker assembly.

FIG. 2 shows a front view of the loudspeaker assembly.

### DETAILED DESCRIPTION OF THE PREFERRED EMBODIMENT

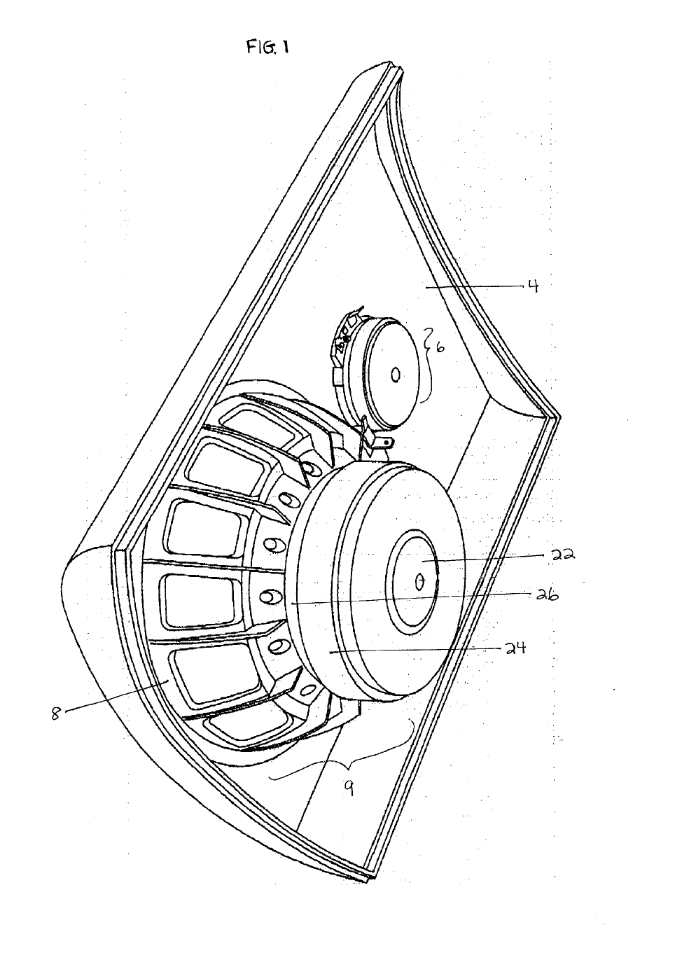

In a preferred embodiment, the loudspeaker assembly 2 of the present invention is generally comprised of a baffle 4, a tweeter assembly 6, a woofer frame 8 which is integral component of the baffle 4, and a woofer assembly 9 as depicted in FIG. 1. While the loudspeaker assembly 2 described herein is comprised of a tweeter assembly 6 and a woofer assembly 9, any combination of high frequency and low frequency transducers may be used.

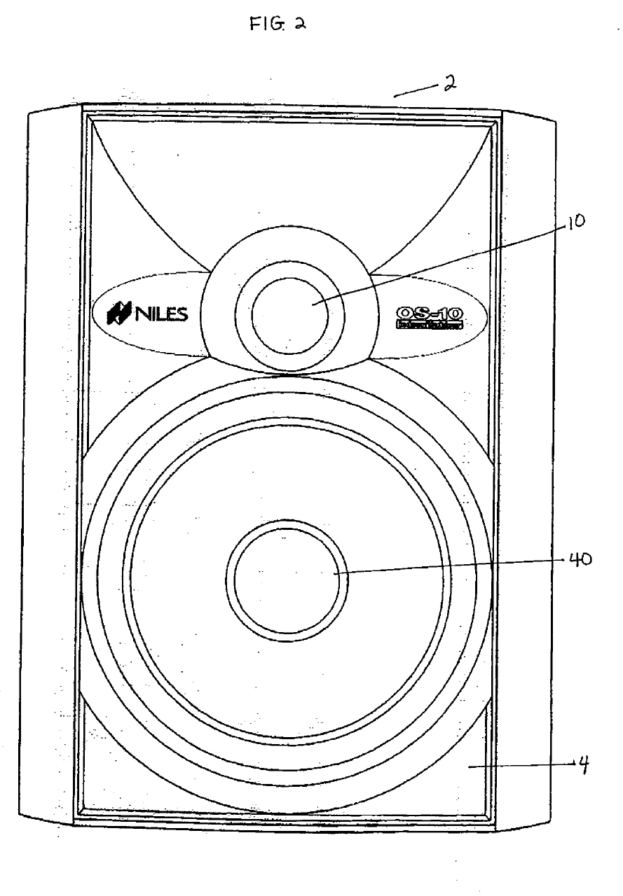

The tweeter assembly 6 could be of any variety known in the art, such as those shown and described in U.S. Pat. No. 6,070,694 to Burdett, et al. and U.S. Pat. No. D461,464 to Sterns, et al. The tweeter assembly 6 is securely affixed to the baffle 4 in such a fashion as to enable the projection of sound from the high frequency transducer 10 outward from the face of the baffle 4. As shown in FIG. 2, the high frequency transducer 10 is positioned such that sound waves emanating from the high frequency transducer 10 are not deflected by the baffle 4, thereby offering higher audio performance.

Additionally, the low frequency transducer 40 is positioned such that sound waves emanating from the low frequency transducer 40 are not deflected by the baffle 4, thereby offering higher audio performance. This is due in part to the unique construction of the integrated baffle 4 and woofer frame 8, which allows the woofer assembly 9, which includes the low frequency transducer 40, to be to be mounted into the face of the loudspeaker assembly 2 from the front of the loudspeaker, leaving no ledge on the baffle's 4 woofer opening with which sound may be deflected.

Integral to the baffle 4 is the woofer frame 8. The woofer assembly 9 is located partly within the woofer frame 8 and is comprised of components known in the art. In a preferred embodiment, the woofer assembly 9 is comprised of a back plate 22, a magnet 24, a top plate 26, and a low frequency transducer 40, which is comprised of a coil, a spider, a surround and a cone. The spider is used in conjunction with the surround to suspend the cone at the top and bottom. The back plate 22 is shaped so that the pole section fits through a circular hole cut out of the middle of the magnet 24. The baffle 4 plays an integral part in the construction of the woofer frame 8. Components 20-26 are securely affixed to the back of the baffle 4, while the remaining components are affixed to the front of the baffle 4. Further, by forming the woofer frame 8 as an integral part of the baffle 4, the loudspeaker assembly 2 can accommodate a larger woofer than would normally fit in a same sized baffle 4 and woofer frame 8. The loudspeaker assembly 2 also allows the loudspeaker to produce higher bass output from smaller cabinets, due to greater woofer cone area that the integrated woofer frame 8 and baffle 4 construction makes possible.

Because the baffle 4 is integrally formed with the woofer frame 8, the unitary component functions as the assembly superstructure for the woofer and a standard stamped woofer frame is not required. Elimination of this standard woofer frame reduces the amount of space the woofer assembly 9 occupies. Accordingly, a larger woofer assembly 9 can be fit into the loudspeaker assembly 2. This unitary baffle 4 and woofer frame 8 component also eliminates the manpower required to attach a standard woofer frame to a baffle.

While this is the preferred embodiment, different woofer assembly 9 configurations with different component parts can be used. The woofer assembly 9 is positioned such that the low frequency sound it emanates projects from the front of the baffle 4, and ideally without diffraction from the baffle 4 for higher fidelity audio performance. This is due in part to the novel integrated baffle 4 and woofer frame 8 component, which allows the low frequency transducer 40 to be to be mounted into the face of the loudspeaker assembly 2, leaving no ledge on the baffle's 4 woofer opening with which sound may be deflected. The integral construction also causes the cone to be more forward than typical installation and flush with the face of the baffle. The integral construction of the baffle 4 and the woofer frame 8 is also safer for the environment as the woofer assembly 9 is sealed into the baffle 4 by design. The glue from the surround, which is applied during installation of the low frequency transducer 40, automatically acts to seal the woofer assembly 9. The above components are operationally connected to a power source and electronics which enable the loudspeaker assembly 2 to produce the desired audio output.

Improvement to audio performance is achieved by the present invention in part because the baffle 4 and integral woofer frame 8 are non-metallic, preferably plastic. A non-ferrous woofer frame does not absorb magnetic energy from the motor system of the speaker, thus providing heightened audio output and clarity relative to the traditional speaker with a metal woofer frame. In a preferred embodiment, the loudspeaker assembly 2 can be utilized both in an indoor or outdoor environment. Thus, the non-metallic nature of the baffle 4 and integral woofer frame 8 improves the weather resistance of the assembly 2 in addition to improving audio performance.

In another embodiment, the loudspeaker assembly 2 may contain a smaller magnet 24 while producing the same output of a larger magnet, because the woofer frame 8 does not absorb magnetic energy as atraditional woofer frame would. This would save costs in the manufacture of loudspeakers while retaining high quality sound and would also allow the loudspeaker to be lighter in weight.

In addition, because the woofer frame 8 and the baffle 4 are an integral, unitary component, the hand labor required to install the woofer frame is eliminated. There is no need for a separate woofer frame to be made and installed on the baffle.

Accordingly, it will be understood that the preferred embodiment of the present invention has been disclosed by way of example and that other modifications and alterations may occur to those skilled in the art.

What is claimed is:

1. A loudspeaker assembly, comprising:
a baffle, wherein said baffle is constructed of a non-metallic substance;
a tweeter assembly attached to said baffle;
a woofer frame, wherein said woofer frame is an integral part of said baffle; and,
a woofer assembly, wherein said woofer assembly is mounted within said woofer frame.

2. The loudspeaker assembly of claim 1, wherein said woofer assembly consists of a back plate, a magnet, a top plate, and a low frequency transducer.

3. The loudspeaker assembly of claim 2, wherein said low frequency transducer is comprised of a coil, a spider, a surround and a cone.

4. The loudspeaker assembly of claim 2, wherein said woofer assembly is installed into said loudspeaker by mounting the woofer assembly from the front of the loudspeaker.

5. The loudspeaker assembly of claim 1, wherein said woofer frame is created as an integral part of the baffle by molding the woofer frame and the baffle as a unitary component.

6. The loudspeaker assembly of claim 1, wherein said loudspeaker assembly is used in an outdoor setting.

7. The loudspeaker assembly of claim 1, wherein said non-metallic baffle is reinforced to reduce flex.

8. A loudspeaker assembly for outdoor use, comprising:
a baffle, wherein said baffle is constructed of a non-metallic substance;
a tweeter assembly attached to said baffle;
a woofer frame, wherein said woofer frame is an integral part of said baffle; and,
a woofer assembly, wherein woofer assembly is mounted within said woofer frame.

9. The loudspeaker assembly of claim 8, wherein said woofer assembly consists of a back plate, a magnet, a top plate and a low frequency transducer.

10. The loudspeaker assembly of claim 9, wherein said low frequency transducer is comprised of a coil, a spider, a surround and a cone.

11. The loudspeaker assembly of claim 8, wherein said woofer assembly is installed into said loudspeaker by mounting the woofer assembly from the front of the loudspeaker.

12. The loudspeaker assembly of claim 8, wherein said woofer frame is created as an integral part of the baffle by molding the woofer frame and the baffle as a unitary component.

13. The loudspeaker assembly of claim 8, wherein said non-metallic baffle is reinforced to reduce flex.

14. A loudspeaker assembly for outdoor use, comprising:
a baffle, wherein said baffle is constructed of a non-metallic substance;
a tweeter assembly attached to said baffle;
a woofer frame, wherein said woofer frame is an integral part of said baffle; and,
a woofer assembly, wherein said woofer assembly is mounted within said woofer frame, and said woofer assembly consists of a back plate, a magnet, a top plate, and a low frequency transducer, said low frequency transducer comprising a coil, a spider, a surround and a cone.

15. The loudspeaker assembly of claim 14, wherein said non-metallic baffle is reinforced to reduce flex.

16. The loudspeaker assembly of claim 14, wherein said woofer frame is created as an integral part of the baffle by molding the woofer frame and the baffle as a unitary component.

17. A loudspeaker assembly wherein a woofer frame and a baffle are one unitary component of said loudspeaker.

18. The loudspeaker assembly of claim 17, wherein the woofer frame is created as an integral part of the baffle by molding the woofer frame and the baffle as a unitary component.

19. The loudspeaker assembly of claim 17, wherein a woofer assembly is mounted within the woofer frame.

20. The loudspeaker assembly of claim 19, wherein said low frequency transducer is comprised of a coil, a spider, a surround and a cone.

21. The loudspeaker assembly of claim 17, further including a woofer assembly consisting of a back plate, a magnet, a top plate and a low frequency transducer.

22. The loudspeaker assembly of claim 19, wherein said woofer assembly is installed into said loudspeaker by mounting the woofer assembly from the front of the loudspeaker.
